(19) United States
(12) Patent Application Publication
(10) Pub. No.: US 2024/0124230 A1
(43) Pub. Date: Apr. 18, 2024

(54) INTER-FLOOR TRANSPORT SYSTEM AND METHOD OF DRIVING THE SAME

(71) Applicant: SAMSUNG ELECTRONICS CO., LTD., Suwon-si (KR)

(72) Inventors: Youn Gon Oh, Suwon-si (KR); Ji Hun Kim, Suwon-si (KR); Sang Hyuk Park, Suwon-si (KR); Young-Kyu Kim, Suwon-si (KR)

(73) Assignee: SAMSUNG ELECTRONICS CO., LTD., Suwon-si (KR)

(21) Appl. No.: 18/217,058

(22) Filed: Jun. 30, 2023

(30) Foreign Application Priority Data
Oct. 12, 2022 (KR) 10-2022-0130576
Mar. 7, 2023 (KR) 10-2023-0029841

(51) Int. Cl. B65G 1/06; B65G 1/04; B65G 49/06

(52) U.S. Cl. CPC B65G 1/065; B65G 1/0414; B65G 49/062; B65G 49/067; B65G 2201/0297

(57) ABSTRACT

An inter-floor transport system includes a first interface unit at a first floor and configured to receive containers from a transport vehicle, and a car configured to receive containers from the first interface unit at the first floor and move containers to a second floor, where the car includes a cage, a storage unit in the cage and including a plurality of storage areas, and an arrangement unit in the cage, the arrangement unit being configured to receive containers from the first interface unit and store containers in respective storage areas of the plurality of storage areas of the storage unit.

### CROSS-REFERENCE TO RELATED APPLICATION

This application is based on and claims priority to Korean Patent Application No. 10-2023-0029841, filed on Mar. 7, 2023, in the Korean Intellectual Property Office, and Korean Patent Application No. 10-2022-0130576, filed on Oct. 12, 2022, in the Korean Intellectual Property Office, the disclosures of which are incorporated herein by reference in their entireties.

### BACKGROUND

### 1. Field

Example embodiments of the disclosure relate to an inter-floor transport system and a method of driving the same.

### 2. Description of the Related Art

When substrate processing equipment is installed over multiple floors (for example, upper and lower floors) in a fabrication facility or a fab, a tower lift is needed to transport containers between the floors. Openings need to be formed at each of the floors to enable vertical movement of container transport units (e.g., carriages) of the tower lift.

However, as the levels of the fabrication facility increase in height, it becomes more difficult to align the openings at each of the floors. If the height of the fabrication facility is doubled, alignment error of the openings may also be doubled. That is, alignment between the openings may not be able to be guaranteed.

The container transport units may vertically move by receiving power via belts, and as the height of the fabrication facility increases, it may be difficult to properly set the belts to have an appropriate tension. In this case, wheel guides may be used, but as wheels are vulnerable to friction, particles may easily be generated, raising the issue of contamination.

Alternatively, two tower lifts may be connected. In this case, however, dead space may be formed due to the space for connecting the two tower lifts.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide an inter-floor transport system capable of stably transporting containers regardless of the height of a fab, which may improve straightness between openings, and may efficiently utilize space.

One or more example embodiments provide a method of driving an inter-floor transport system capable of stably transporting containers regardless of the height of a fab, which may improve straightness between openings, and may efficiently utilize space.

Additional aspects will be set forth in part in the description which follows and, in part, will be apparent from the description, or may be learned by practice of the presented embodiments.

According to an aspect of an example embodiment, an inter-floor transport system may include a first interface unit at a first floor and configured to receive containers from a transport vehicle, and a car configured to receive containers from the first interface unit at the first floor and move containers to a second floor, where the car may include a cage, a storage unit in the cage and including a plurality of storage areas, and an arrangement unit in the cage, the arrangement unit being configured to receive containers from the first interface unit and store containers in respective storage areas of the plurality of storage areas of the storage unit.

According to an aspect of an example embodiment, an inter-floor transport system may include a first interface unit at a first floor and configured to receive containers from a transport vehicle and a car configured to receive containers from the first interface unit at the first floor and move containers to a second floor, where the car may include a cage, a storage unit in the cage and including a plurality of storage areas and an arrangement unit in the cage, the arrangement unit being configured to receive containers from the first interface unit and store containers in respective storage areas of the plurality of storage areas of the storage unit, where, while the car is moving, the arrangement unit may be configured to change positions of containers, where the first interface unit may include a first interface layer and a second interface layer on the first interface layer, where the storage unit may include a first inner layer and a second inner layer respectively corresponding to the first interface layer and the second interface layer, where containers delivered from the first interface layer may be stored in the first inner layer, where containers delivered from the second interface layer may be stored in the second inner layer, where the arrangement unit may include a plurality of unit conveyors in each of the first inner layer and the second inner layer, the plurality of unit conveyors being configured to move containers, where the plurality of unit conveyors may be configured to move containers to respective neighboring unit conveyors of the plurality of unit conveyors or temporarily hold containers, where the first interface unit may be configured to receive containers at first loading/unloading points, and where, when viewed from above, the first loading/unloading points may not covered by the second interface layer.

According to an aspect of an example embodiment, a method of driving an inter-floor transport system, the inter-floor transport system including a first interface unit at a first floor and a car configured to move between the first floor and a second floor, the car including a storage unit and an arrangement unit, may include receiving, by the first interface unit, containers from a transport vehicle, delivering, by the first interface unit, the containers to the arrangement unit of the car and changing, by the arrangement unit, positions of the containers in the car by moving the containers while the car is moving.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram of an inter-floor transport system according to some embodiments of the present disclosure;

FIG. 2 is a perspective view illustrating a car and a moving space according to some embodiments of the present disclosure;

FIG. 3 is a perspective view illustrating a plurality of inner layers according to some embodiments of the present disclosure;

FIGS. 4 and 5 are diagrams illustrating container movement within a car according to some embodiments of the present disclosure;

FIG. 6 is a perspective view of an inter-floor transport system according to some embodiments of the present disclosure;

FIG. 7 is a perspective view illustrating an arrangement unit according to some embodiments of the present disclosure;

FIG. 8 is a perspective view illustrating an arrangement unit that is loaded with a plurality of containers according to some embodiments of the present disclosure;

FIG. 9 is a perspective view illustrating storage units according to some embodiments of the present disclosure;

FIGS. 10, 11 and 12 are diagrams illustrating operations of the inter-floor transport system according to some embodiments of the present disclosure;

FIG. 13 is a perspective view illustrating an interface unit of the inter-floor transport system according to some embodiments of the present disclosure;

FIG. 14 is a perspective view illustrating an interface unit that is loaded with containers according to some embodiments of the present disclosure;

FIG. 15 is a perspective view illustrating an interface of the inter-floor transport system according to some embodiments of the present disclosure;

FIG. 16 is a perspective view illustrating an operation of an interface unit according to some embodiments of the present disclosure;

FIGS. 17, 18, 19, 20, 21 and 22 are diagrams illustrating intermediate operations of a method of driving an inter-floor transport system according to some embodiments of the present disclosure; and

FIGS. 23, 24, 25, 26, 27, 28, 29, 30 and 31 are diagrams illustrating intermediate operations of a method of driving an inter-floor transport system according to some embodiments of the present disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

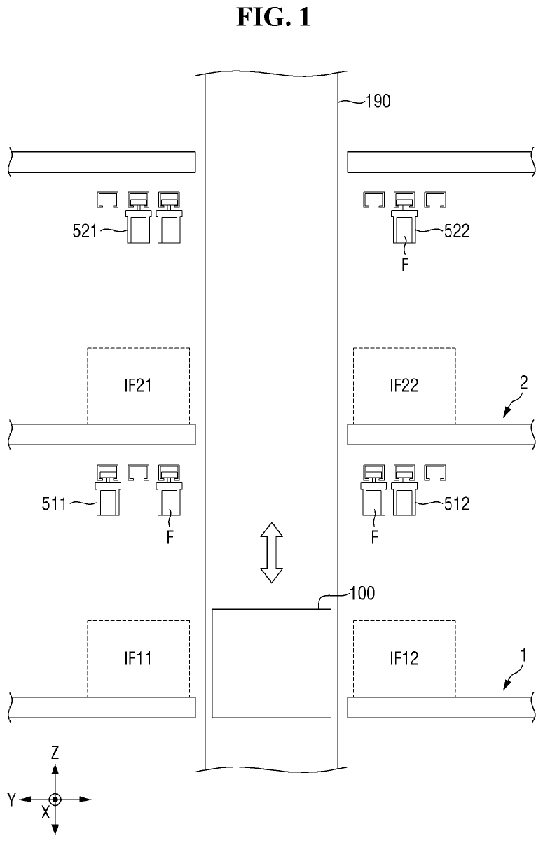

FIG. 1 is a diagram of an inter-floor transport system according to some embodiments of the present disclosure.

Referring to FIG. 1, a fabrication facility may have multiple floors (e.g., first and second floors 1 and 2), and at least one substrate processing apparatus may be installed at each of the first and second floors 1 and 2. For convenience, the fabrication facility is illustrated as having only two floors, but may actually have three or more floors.

The inter-floor transport system may move containers F between the first and second floors 1 and 2. For example, the containers F may be front-opening unified pods (FOUPs) or front opening shipping boxes (FOSBs), but the present disclosure is not limited thereto.

The inter-floor transport system may include interface units IF11 and IF12, which are installed at the first floor 1, interface units IF21 and IF22, which are installed at the second floor 2, and a car 100, which moves between the first and second floors 1 and 2. The car 100 may move vertically (i.e., in a third direction Z) along a moving space 190.

Transport vehicles 511, 512, 521, and 522 may be installed the first and second floors 1 and 2. For example, the transport vehicle 511 may be installed at the first floor 1, on one side (i.e., on the left side, in a second direction Y) of the moving space 190, and the transport vehicle 512 may be installed at the first floor 1, on the other side (i.e., on the right side, in the second direction Y) of the moving space 190. The transport vehicle 521 may be installed at the second floor 2, on one side (i.e., on the left side, in the second direction Y) of the moving space 190, and the transport vehicle 522 may be installed at the second floor 2, on the other side (i.e., on the right side, in the second direction Y) of the moving space 190. The transport vehicles 511, 512, 521, and 522 may be overhead hoist transports (OHTs), but the present disclosure is not limited thereto. Alternatively, the transport vehicles 511, 512, 521, and 522 may be automated guide vehicles (AGVs), autonomous mobile robots (AMR), etc.

Each of the interface units IF11, IF12, IF21, and IF22 may receive containers from a transport vehicle. For example, the interface unit IF11, may receive the containers F from the transport vehicle 511, which is installed at the first floor 1. Then, the car 100 may receive the containers F from the interface unit IF11. The car 100 may transport the containers F to the second floor 2 and may deliver the containers F to, for example, the interface unit IF22 on the second floor 2. Then, the containers F that are on standby in the interface unit IF22 may be picked up by the transport vehicle 522 and may then be transported to a destination.

The car 100 may receive the containers F from the interface unit IF12, on the first floor 1 and may deliver the containers F to the interface unit IF22 on the second floor 2.

The car 100 may receive the containers F from the interface unit IF11 on the first floor 1 and may deliver the containers F to the interface unit IF21 on the second floor 2.

The car 100 may receive the containers F from the interface unit IF21 on the second floor 2 and may deliver the containers F to the interface unit IF12 on the first floor 1.

The car 100 may receive the containers F from the interface unit IF22 on the second floor 2 and may deliver the containers F to the interface unit IF12 on the first floor 1.

The car 100 may deliver the containers F through various routes in accordance with instructions from an upper controller.

While the car 100 is transporting the containers F, the operator may not be in the car 100. That is, the car 100 may transport only the containers F without the operator present therein.

When the car 100 is transporting the containers F (i.e., when the car 100 is moving), the positions of the containers F in the car 100 may be changed. For example, the containers F may be moved to a storage area in the car 100 while being transported. For example, the positions of the containers F in the car 100 may be changed in the order in which to unload the containers F. As the positions of the containers F in the car 100 are changed while the containers F are being transported, the amount of time taken to transport the containers F can be reduced.

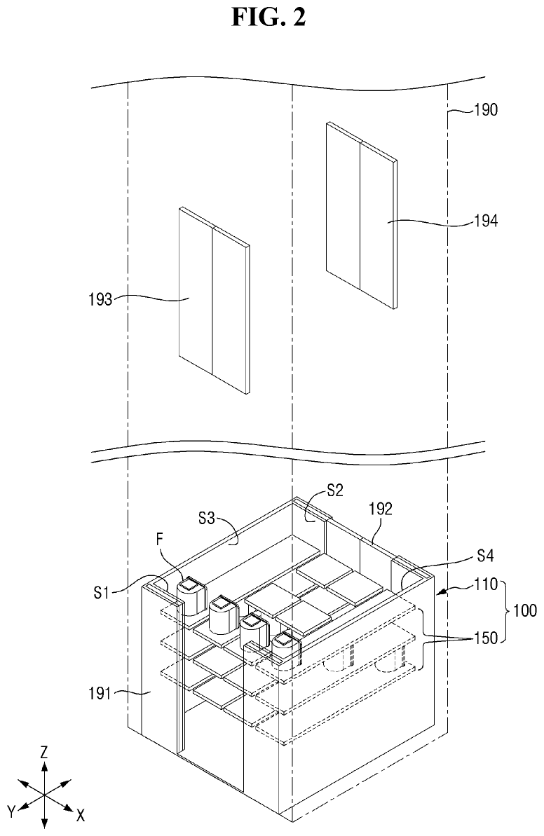

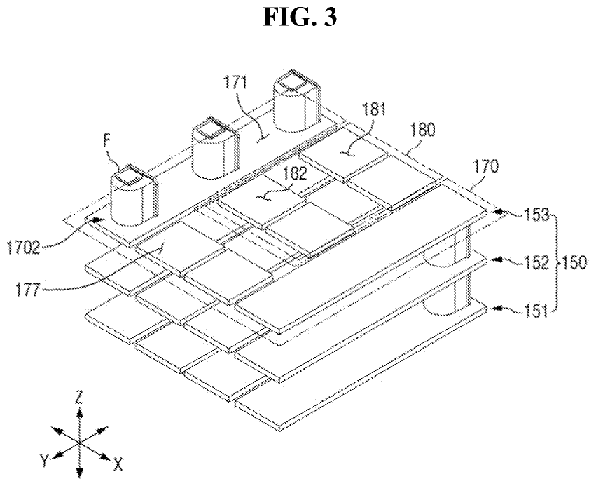

FIG. 2 is a perspective view illustrating a car and a moving space (e.g., the car and the moving space of FIG. 1) according to some embodiments of the present disclosure. FIG. 3 is a perspective view illustrating a plurality of inner layers according to some embodiments of the present disclosure.

Referring to FIGS. 2 and 3, the car 100 may move vertically along the moving space 190. Doors 191 and 192 may be installed at the first floor 1 in the moving space 190. The door 191 may face the interface unit IF11, and the door 192 may face the interface unit IF12. Doors 193 and 194 may be installed at the second floor 2 in the moving space 190. The door 193 may face the interface unit IF21, and the door 194 may face the interface unit IF22.

A cage 110 may have first, second, third, and fourth sides S1, S2, S3, and S4. The first and second sides S1 and S2 may be opposite to each other, and the third and fourth sides S3 and S4 may be opposite to each other.

The first side S1 may face the interface units IF11 and IF21 as well as the doors 191 and 193, and the second side S2 may face the interface units IF12 and IF22 as well as the doors 192 and 194.

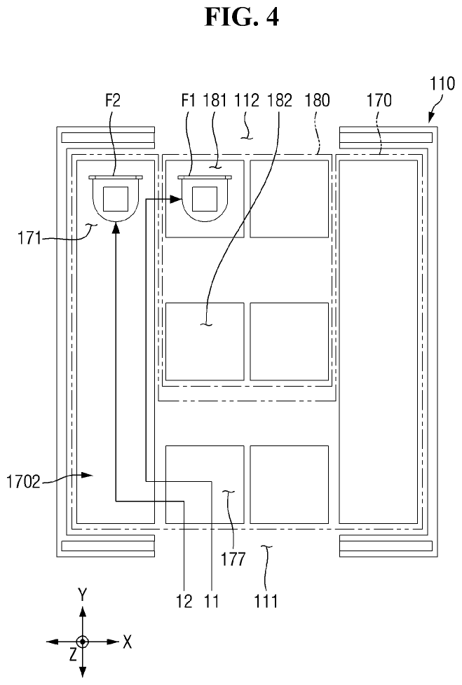

An entrance (e.g., entrance 111 of FIG. 4) of the car 100 may be installed at the first side S1, and an exit (e.g., exit 112 of FIG. 4) of the car 100 may be installed at the second side S2.

The car 100 may include the cage 110 and a plurality of inner layers 150, which are arranged in the cage 110 in a vertical direction (i.e., in the third direction Z).

The inner layers 150 may include, for example, three inner layers, such as first, second, and third inner layers 151, 152, and 153. The first inner layer 151 may be a bottom layer, the second inner layer 152 may be a middle layer, and the third inner layer 153 may be a top layer.

Each of the first, second, and third inner layers 151, 152, and 153 may include a storage unit 180 and an arrangement unit 170. For convenience of description, a single arrangement unit 170 and a single storage unit 180 are described.

The storage unit 180 may include a plurality of storage areas. The arrangement unit 170 may receive containers F from one of the interface units IF11, IF12, IF21, and IF22 and may store the containers F in the respective storage areas of the storage unit 180.

Each of the storage unit 180 and the arrangement unit 170 may include one or more unit conveyors capable of moving the containers F, but the present disclosure is not limited thereto. The unit conveyors may move the containers F to a respective neighboring unit conveyors or may temporarily hold the containers F. The unit conveyors may have a structure for moving the containers F and/or changing directions. The unit conveyors may be configured as moving conveyors only for moving the containers F or may be configured as diverter conveyors capable of changing directions.

Referring to FIG. 3, the arrangement unit 170 may be installed at the first side S1 of the cage 110 (for example, on part of the first side S1 near the entrance 111 of FIG. 4) and on the third and fourth sides S1, S3, and S4 of the cage 110. The storage unit 180 may be installed at the second side S2 of the cage 110 (for example, on part of the second side S2 near the exit 112 of FIG. 4) and in the middle of the cage 110.

The arrangement unit 170 of may include an entrance area 177, which may be disposed adjacent to the first side S1, and arrangement conveyors 1702, which may be disposed on the third or fourth side S3 or S4. Each of the arrangement conveyors 1702 may include, for example, three unit conveyors, but the present disclosure is not limited thereto. The storage unit 180 may include storage areas 181, which may be disposed adjacent to the second side S2, and buffers 182, which may be disposed between the arrangement conveyors 1702 of a corresponding inner layer, on the third and fourth sides S3 and S4.

Specifically, for example, when the third inner layer 153 is fully loaded, a total of 12 containers F (i.e., four rows of containers F in the first direction X and three rows of containers F in the second direction Y) may be arranged in the third inner layer 153. In each of the storage units of the first second, and third inner layers 151, 152, and 153, a total of four containers F may be arranged in two rows in the first direction X and two rows in the second direction Y. In each of the arrangement units of the first, second, and third inner layers 151, 152, and 153, a total of eight containers F (i.e., three containers on each of the two conveyors 1702 of the corresponding inner layer and two containers on the entrance area 177 of the corresponding inner layer) may be arranged.

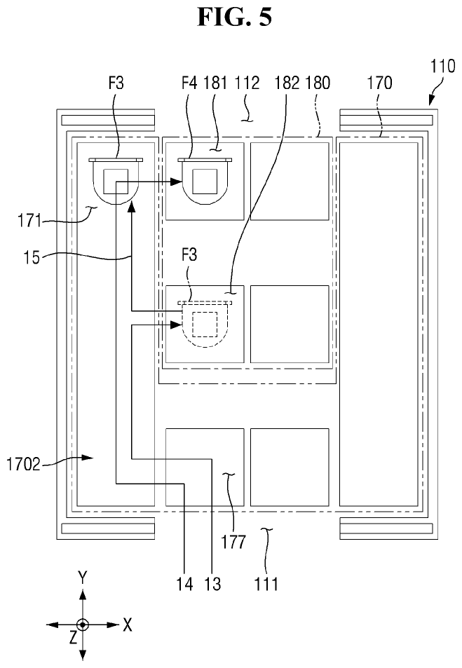

FIGS. 4 and 5 are diagrams illustrating container movement within a car according to some embodiments of the present disclosure. The entrance 111 and the exit 112 may be disposed at two opposite positions in the cage 110.

Referring to FIG. 4, a plurality of containers (e.g., first and second containers F1 and F2) may be driven in a first-in-first-output (FIFO) manner. That is, the first and second containers F1 and F2 may be sequentially loaded in, and unloaded from, the cage 110.

Specifically, the first container F1 may be delivered from the interface unit IF11 on the first floor 1 to an entrance area 177 of an arrangement unit 170 through the entrance 111. The conveyors of the arrangement unit 170 may deliver the first container F1 to a storage area 181, among a plurality of storage areas of a storage unit 180, as indicated by path 11.

Thereafter, the second container F2 may be delivered to the entrance area 177 of the arrangement unit 170 through the entrance 111. The conveyors of the arrangement unit 170 may deliver the second container F2 to an area of the arrangement unit 170 adjacent to the storage area 181 (i.e., to an area 171), as indicated by path 12.

Thereafter, when the car 100 arrives at the second floor 2, the first container F1 may be delivered first to the interface unit IF22 through the exit 112, and then, the second container F2 may be delivered to the interface unit IF22 through the storage area 181 and the exit 112.

Referring to FIG. 5, a plurality of containers (e.g., third and fourth containers F3 and F4), may be driven in a last-in-first-out (LIFO) manner. That is, the third and fourth containers F3 and F4 may be sequentially loaded in the cage 110, but may be unloaded from the cage 110 in the opposite order.

Specifically, the third container F3 may be delivered from the interface unit IF11 on the first floor 1 to the entrance area 177 of the arrangement unit 170 through the entrance 111. The conveyors of the arrangement unit 170 may deliver the third container F3 to a buffer 182, among the storage areas of a storage unit 180, as indicated by path 13.

Thereafter, the fourth container F4 may be delivered to the entrance area 177 of the arrangement unit 170 through the entrance 111. The conveyors of the arrangement unit 170 may deliver the fourth container F4 to the storage area 181, which is one of the storage areas of the storage unit 180 that is adjacent to the exit 112), as indicated by path 14.

Thereafter, the third container F3 may be delivered from the buffer 182 to the area 171, as indicated by path 15. As a result, the fourth container F4 may be disposed closer than the third container F3 to the exit 112.

Thereafter, when the car 100 arrives at the second floor 2, the fourth container F4 may be delivered first to the interface unit IF22 through the exit 112, and then, the third container F3 may be delivered to the interface unit IF22 through the storage area 181 and the exit 112.

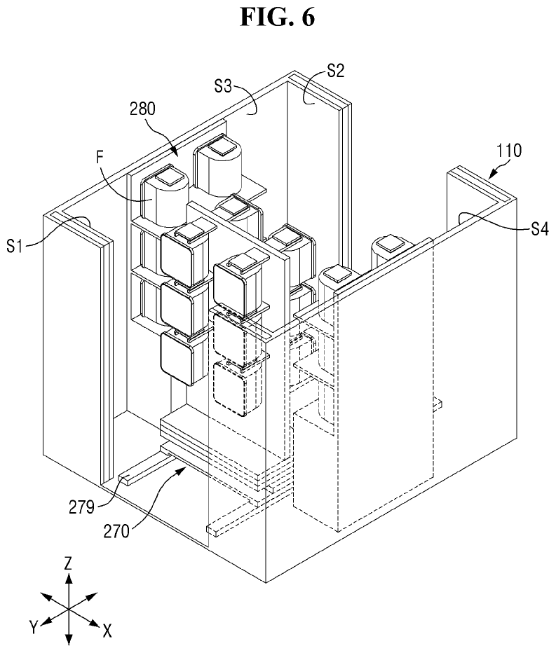

FIG. 6 is a perspective view of an inter-floor transport system according to some embodiments of the present disclosure.

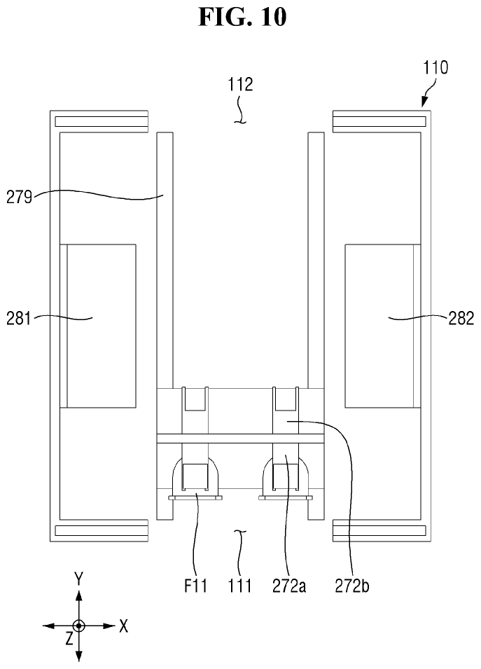

Referring to FIG. 6, an entrance (111 of FIG. 10) may be installed on a first side S1 of a cage 110, and an exit (112 of FIG. 10) may be installed on a second side S2 of the cage 110. Rails 279, which extend from the entrance 111 to the exit 112 of the cage 110, may be installed. An arrangement unit 270 may move along the rails 279.

Storage units 280, which may include a plurality of storage areas, may be installed on a third side S3 and/or a fourth side S4 of the cage 110. The storage units 280 may be disposed to be spaced apart from each other in a first direction X. The arrangement unit 270 may receive containers F from an interface unit (for example, IF11) and may store the containers F in the respective storage areas in the storage units 280.

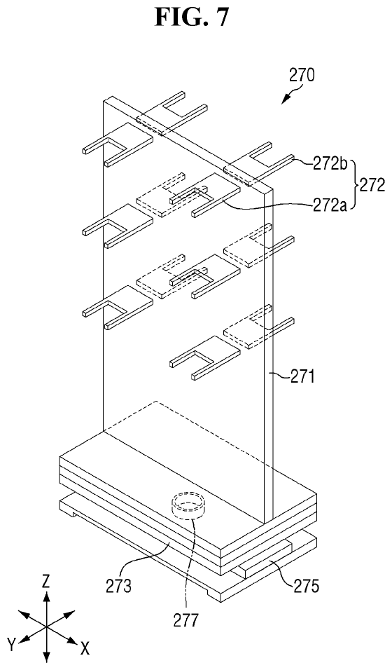

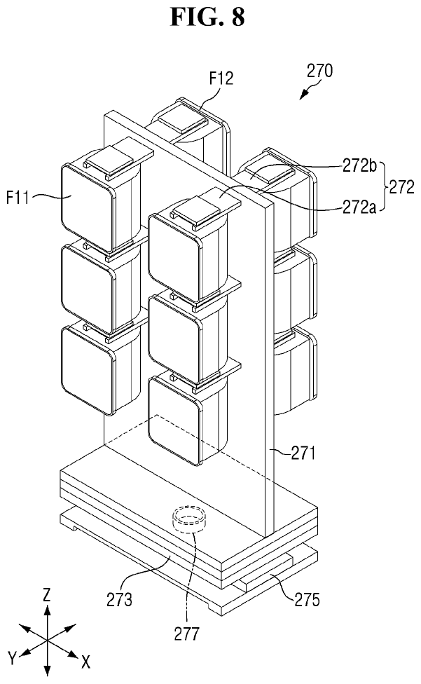

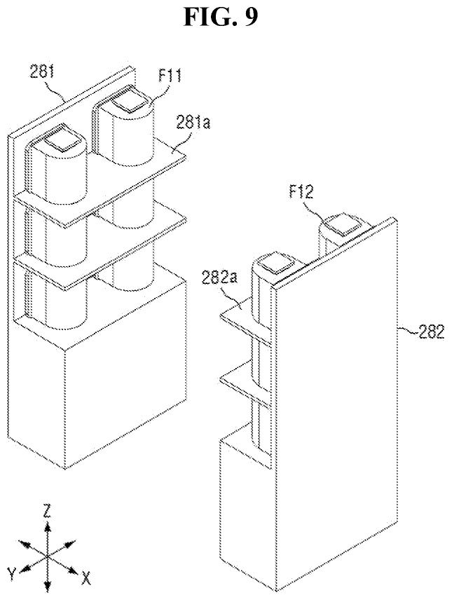

FIG. 7 is a perspective view illustrating an arrangement unit according to some embodiments of the present disclosure. FIG. 8 is a perspective view illustrating an arrangement unit that is loaded with a plurality of containers according to some embodiments of the present disclosure. FIG. 9 is a perspective view illustrating storage units according to some embodiments of the present disclosure. FIGS. 7-9 may illustrate aspects of FIG. 6, but the description of FIGS. 7-9 is not limited thereto.

Referring to FIGS. 7 and 8, the arrangement unit 270 may include a body 271, a plurality of supports 272, and a driver, which may include slider 273, lift 275 and rotator 277.

The body 271 may be in the shape of a plate extending in a third direction Z.

The supports 272 may be installed at the body 271 and may support a plurality of containers (F11 and F12). The supports 272 may be installed on both sides of the body 271. The supports 272 may include first supports 272a, which may be installed on one side (hereinafter, the first side) of the body 271, and second supports 272b, which may be installed on the other side (hereinafter, the second side) of the body 271. The first supports 272a and the second supports 272b may be arranged in a matrix (e.g., in a 2×3 matrix). When the first supports 272a and the second supports 272b are both fully loaded, six containers F11 may be disposed on the first side of the body 271, and six containers F12 may be disposed on the second side of the body 271.

The driver (which may include slider 273, lift 275 and rotator 277), which may be configured to move the body 271, may perform at least one of, for example, a horizontal movement operation, a vertical movement operation, and a rotation operation. To this end, the driver may include a slider 273, a lift 275, and a rotator 277. The slider 273 may move the body 271 in a horizontal direction along the rails 279, the lift 275 may lift up or down the body 271 in a vertical direction, and the rotator 277 may rotate the body 271.

Referring to FIG. 9, the storage units (e.g., 280 of FIG. 6) may be installed on at least one of the third and fourth sides S3 and S4 of the cage 110. The storage units 280 may include a first storage unit 281. The first storage unit 281, which may be installed on the third side S3 of the cage 110 and may include a plurality of first storage areas 281a, and a second storage unit 282, which may be installed on the fourth side S4 of the cage 110, may include a plurality of second storage areas 282a.

The layout of the supports 272 of the arrangement unit 270 may correspond to the layout of the storage areas of each of the storage units 280, and thus, the supports 272 and the storage areas of each of the storage units 280 may be arranged to be able to simultaneously deliver containers (F11 and F12), fixed to the supports 272, to the storage areas of each of the storage units 280. For example, if the supports 272 are arranged in a 2×3 matrix on either side of the body 271, the storage areas of each of the storage units 280 may be arranged in a 2×3, 4×3, or 4×6 matrix.

When the storage units of each of the storage units 280, for example, the first storage areas 281a of the first storage unit 281, are arranged in a 4×3 matrix, the arrangement unit 270 may deliver six containers (F11 and F12) twice to the first storage unit 281. Alternatively, when the first storage areas 281a of the first storage unit 281 are arranged in a 4×6 matrix, the arrangement unit 270 may deliver six containers (F11 and F12) four times to the first storage unit 281.

FIGS. 10, 11 and 12 are diagrams illustrating operations of the inter-floor transport system according to some embodiments of the present disclosure.

Referring to FIG. 10, the first supports 272a may be installed on the first side of the arrangement unit 270 to face the entrance 111. A plurality of containers F11 may be delivered from an interface unit on a first floor to the first supports 272a.

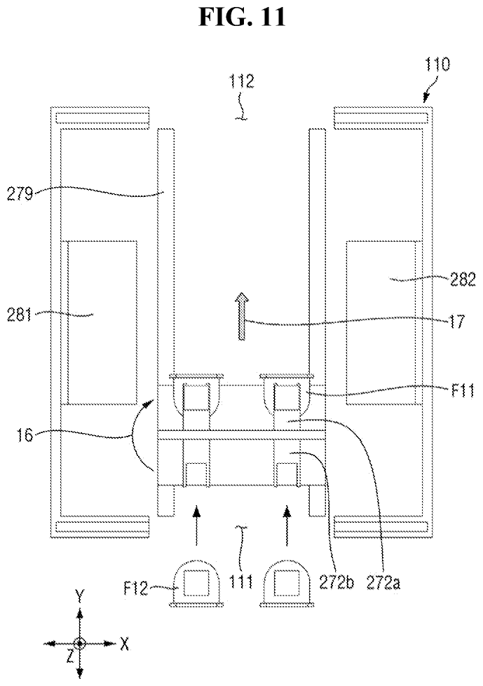

Referring to FIG. 11, the arrangement unit 270 may rotate such that the second supports 272b, which are installed on the second side of the arrangement unit 270, face the entrance 111, as indicated by path 16.

A plurality of containers F12 may be delivered to the second supports 272b. In this manner, the first supports 272a and the second supports 272b may be loaded with the containers F11 and the containers F12, respectively.

The arrangement unit 270 may move along the rails 279, as indicated by path 17.

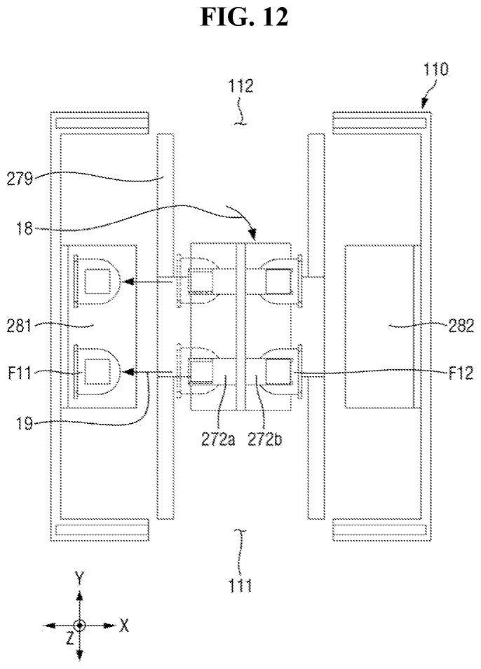

Referring to FIG. 12, the arrangement unit 270 may rotate such that the first and second sides of the arrangement unit 270 face the first and second storage units 281 and 282, respectively, as indicated by path 18.

The containers F11 fixed on the first side of the arrangement unit 270 may be delivered to the first storage areas 281a of the first storage unit 281, as indicated by path 19.

The containers F12 that are fixed on the second side of the arrangement unit 270 may be delivered to the second storage areas 282a of the second storage unit 282.

Thereafter, referring to FIG. 10, the first supports 272a that are currently empty on the first side of the arrangement unit 270 may be loaded again with a plurality of containers F11. Thereafter, referring to FIG. 11, the second supports 272b that are currently empty on the second side of the arrangement unit 270 may be loaded again with a plurality of containers F12. That is, once each of the first and second storage units 281 and 282 is loaded again with six containers F11 or F12 and the arrangement unit 270 is loaded again with a total of 12 containers (F11 and F12), a car may move.

Alternatively, a plurality of containers F11 may be delivered to the first supports 272a that are currently empty, and the car may start to move without any further loading. In this case, the car may move with the arrangement unit 270 loaded with the containers F11, without delivering containers (F11 and F12) to the first and second storage units 281 and 282.

Alternatively, a plurality of containers F11 that are being held by the first supports 272a of the arrangement unit 270 may have different destinations. In this case, some of the containers F11 may be delivered to the first storage unit 281, and some of the containers F11 may continue to be held by the arrangement unit 270.

Then, the car may move to a predefined floor (e.g., a second floor). When the car arrives at the second floor, the containers F11 still being held by the arrangement unit 270 are unloaded first.

Then, the car moves to another predefined floor, for example, a third floor. While the car is moving, the arrangement unit 270 receives the containers F11 from the first storage unit 281. When the car arrives at the third floor, the arrangement unit 270 unloads the received containers F11.

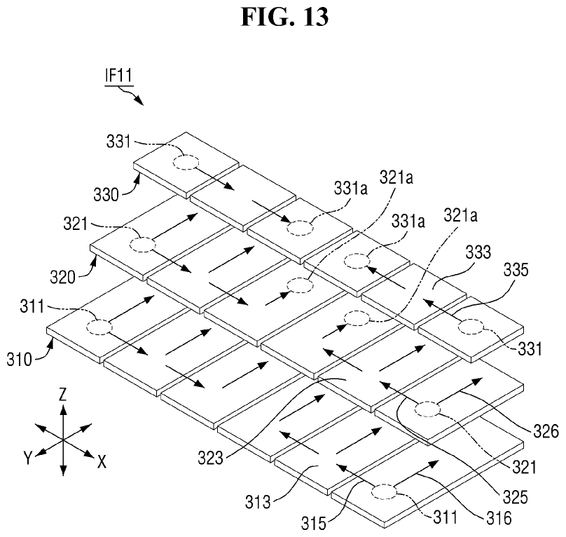

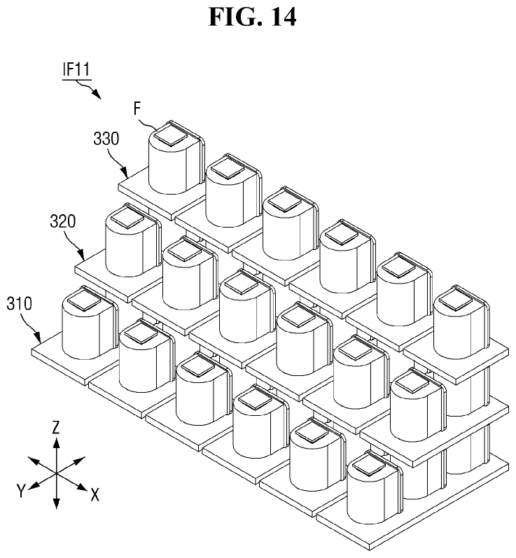

FIG. 13 is a perspective view illustrating an interface unit of the inter-floor transport system according to some embodiments of the present disclosure. FIG. 14 is a perspective view illustrating an interface unit that is loaded with containers according to some embodiments of the present disclosure. For convenience, the embodiments of FIGS. 13 and 14 will hereinafter be described using the interface unit IF11 as an example, but the description that follows may be directly applicable to the other interface units, such as the interface units IF12, IF21, and IF22.

Referring to FIGS. 13 and 14, the interface unit IF11 may include loading/unloading points 311, 321, and 331 where containers F are to be loaded or unloaded by, for example, the transport vehicle 511 of FIG. 1, and in/out points 321a and 331a, which are for delivering containers F to the car 100 (i.e., to the arrangement unit 170 or 270). Containers F may be moved from the loading/unloading points 311, 321, and 331 to the in/out points 321a and 331a using, for example, interface conveyors 313, 323, and 333.

The interface unit IF11 may include a plurality of first, second, and third interface layers 310, 320, and 330. The interface unit IF11 is illustrated as including three interface layers, but may include two interface layers or four or more interface layers.

The first interface layer 310 may include one or more loading/unloading points 311. The first interface layer 310 is illustrated as having two loading/unloading points 311 at either end, in the first direction X, thereof, but the present disclosure is not limited thereto. Containers F may be moved from the loading/unloading points 311 to the respective in/out points of the first interface layer 310 using the interface conveyor 313. The containers F may be moved in the first direction X, as indicated by path 315, and in the second direction Y, as indicated by path 316. In/out points of the first interface layer 310 may be hidden from view in the figures by the second interface layer 320, but may be at positions facing the entrance of the car 100.

The second interface layer 320 may include one or more loading/unloading points 321. The second interface layer 320 is illustrated as having two loading/unloading points 321 at either end, in the first direction X, thereof, but the present disclosure is not limited thereto. Containers F may be moved from the loading/unloading points 321 to respective in/out points 321a of the second interface layer 320 using the interface conveyor 323. The containers F may be moved in the first direction X, as indicated by path 325 or in the second direction Y, as indicated by path 326.

The third interface layer 330 may include one or more loading/unloading points 331. The third interface layer 330 is illustrated as having two loading/unloading points 331 at either end, in the first direction X, thereof, but the present disclosure is not limited thereto. Containers F may be moved from the loading/unloading points 331 to respective in/out points 331a of the third interface layer 330 using the interface conveyor 333. The containers F may be moved in the first direction X, as indicated by path 335.

The first, second, and third interface layers 310, 320, and 330 of the interface unit IF11 may correspond to the first, second, and third inner layers 151, 152, and 153, respectively, of the car 100. That is, containers F from the first interface layer 310 may be stored in the first inner layer 151, containers F from the second interface layer 320 may be stored in the second inner layer 152, and containers F from the third interface layer 330 may be stored in the third inner layer 153.

The interface unit IF11 may include a plurality of unit conveyors. The plurality of unit conveyors may move containers F to their respective neighboring unit conveyors or may temporarily hold containers F.

The plurality of unit conveyors may include one or more diverter conveyors capable of changing the moving direction of containers F. For example, the plurality of unit conveyors corresponding to the loading/unloading points 311 may include diverter conveyors and may thus be able to selectively deliver containers F in the first or second direction X or Y. Unit conveyors to the left of the loading/unloading points 311 may also include diverter conveyors and may thus be able to selectively deliver containers F in the first or second direction X or Y.

When the transport vehicle 511 is an OHT, containers F may be provided from above the interface unit IF11. Thus, only part of a lower interface layer (e.g., the first interface layer 310) may be overlapped by an interface layer (e.g., the second interface layer 320) directly above the lower interface layer. For example, when viewed from above, the loading/unloading points 311 of the first interface layer 310 where containers F can be placed are not hidden from view by the second interface layer 320.

Referring to FIG. 14, a total of 18 containers F (i.e., six rows of containers F in the first direction X and three rows of containers F in the second direction Y) may be arranged in the first interface layer 310, a total of 12 containers F (i.e., six rows of containers F in the first direction X and two rows of containers F in the second direction Y) may be arranged in the second interface layer 320, and a total of six containers F (i.e., six rows of containers F in the first direction X and one row of containers F in the second direction Y) may be arranged in the third interface layer 330.

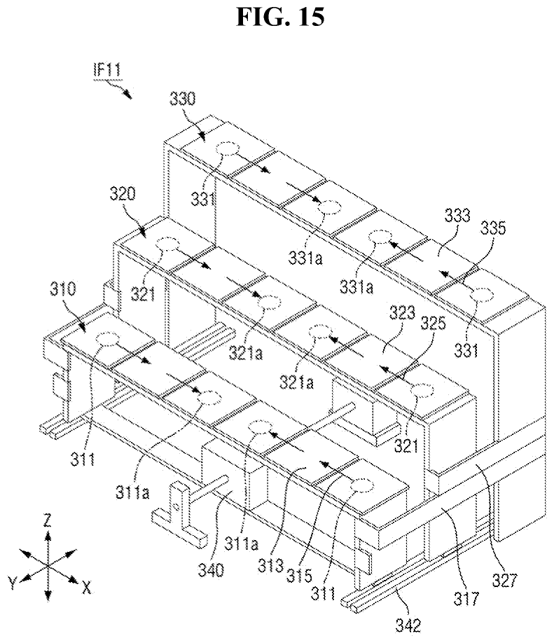

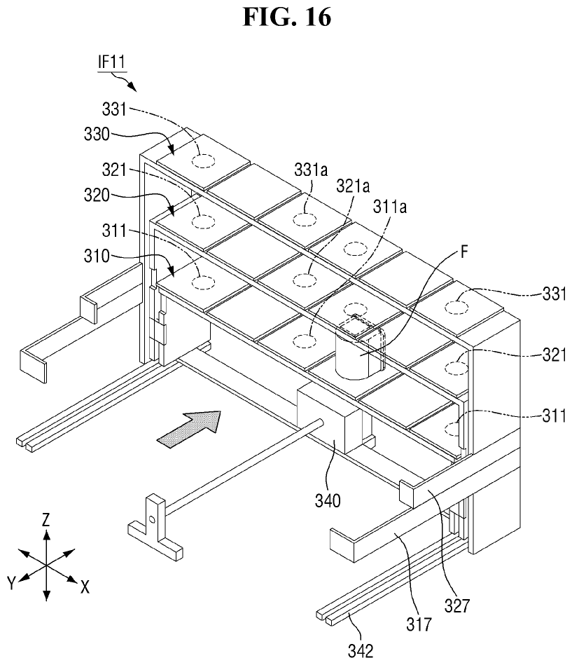

FIG. 15 is a perspective view illustrating an interface of the inter-floor transport system according to some embodiments of the present disclosure. FIG. 16 is a perspective view illustrating an operation of an interface unit according to some embodiments of the present disclosure. For convenience, the embodiment of FIGS. 15 and 16 will hereinafter be described, using the interface unit IF11 as an example, but the description that follows may be directly applicable to the other interface units, such as the interface units IF12, IF21, and IF22. Repeated descriptions of aspects described above may be omitted.

Referring to FIGS. 15 and 16, the interface unit IF11 may include loading/unloading points 311, 321, and 331 where containers F are to be loaded or unloaded by, for example, the transport vehicle 511 of FIG. 1, and in/out points 311a, 321a, and 331a, which are for delivering the containers F to the car 100 (i.e., to the arrangement unit 170 or 270). Containers F may be moved from the loading/unloading points 311, 321, and 331 to the in/out points 311a, 321a, and 331a using, for example, interface conveyors 313, 323, and 333.

The interface unit IF11 may include a plurality of first, second, and third interface layers 310, 320, and 330. A total of six containers F (i.e., six rows of containers F in the first direction X and one row of containers F in the second direction Y) may be arranged in each of the first, second, and third interface layers 310, 320, and 330.

The first and second interface layers 310 and 320, which are a lowermost interface layer and a middle interface layer, respectively, may be moved to be overlapped by the third interface layer 330.

The interface unit IF11 may include a driver 340, which provides a driving force to move the first and second interface layers 310 and 320.

Rails 342 may be installed to guide the moving direction of the first and second interface layers 310 and 320.

Stoppers 317 may be installed to stop the first interface layer 310 from moving beyond a predefined position, and stoppers 327 may be installed to stop the second interface layer 320 from moving beyond the predefined position.

The interface unit IF11 may move between a standby position for receiving containers F and a delivery position for delivering containers F to the car 100.

FIG. 15 illustrates that the interface unit IF11 is at the standby position. Referring to FIG. 15, loading/unloading points 311 of the first interface layer 310, loading/unloading points 321 of the second interface layer 320, and loading/unloading points 331 of the third interface layer 330 are not hidden, but exposed. Accordingly, the transport vehicle 511 may be able to unload containers F at the loading/unloading points 311, 321, and 331. Also, in/out points 311a of the first interface layer 310, in/out points 321a of the second interface layer 320, and in/out points 331a of the third interface layer 330 are not hidden, but exposed.

FIG. 16 illustrates that the interface unit IF11 is at the delivery position. Referring to FIG. 16, the first and second interface layers 310 and 320 may be moved below the third interface layer 330 by the driver 340. As a result, as viewed from above, the first and second interface layers 310 and 320 may be hidden by the third interface layer 330, and the overlapping area of the first and second interface layers 310 and 320 (i.e., part of the first interface layer 310 hidden from view by the second interface layer 320) may be larger when the first interface layer 310 is at the delivery position than when the first interface layer 310 is at the standby position. The loading/unloading points 311 and the in/out points 311a of the first interface layer 310 and the loading/unloading points 321 and the in/out points 321a of the second interface layer 320 may be hidden by the third interface layer 330. Also, the in/out points 311a of the first interface layer 310 and the in/out points 321a of the second interface layer 320 may be positioned adjacent to the entrance of the car 100. Accordingly, containers F at the in/out points 311a of the first interface layer 310 or at the in/out points 321a of the second interface layer 320 may be moved into the car 100.

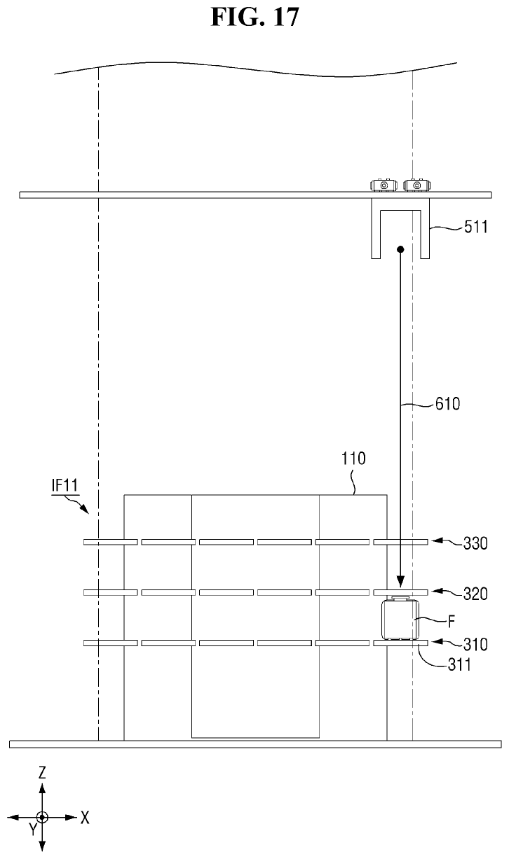

FIGS. 17, 18, 19, 20, 21 and 22 are diagrams illustrating intermediate operations of a method of driving an inter-floor transport system according to some embodiments of the present disclosure. A method of driving an inter-floor transport system according to some embodiments of the present disclosure will hereinafter be described with reference to FIGS. 17 through 22. The inter-floor transport system that will hereinafter be described may be an exemplary inter-floor transport system having the car of FIG. 3 and the interface unit of FIG. 13 applied thereto, but the embodiments are not limited thereto.

Referring to FIG. 17, a transport vehicle 511 may unload a container F at a loading/unloading point 311 of a first interface layer 310 of an interface unit IF11, as indicated by path 610.

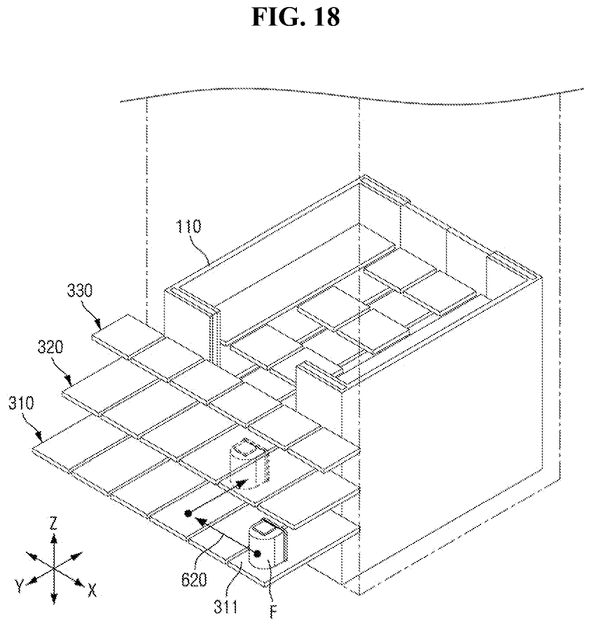

Referring to FIG. 18, the container F may be moved from the loading/unloading point 311 to an in/out point 311a of the first interface layer 310, as indicated by path 620.

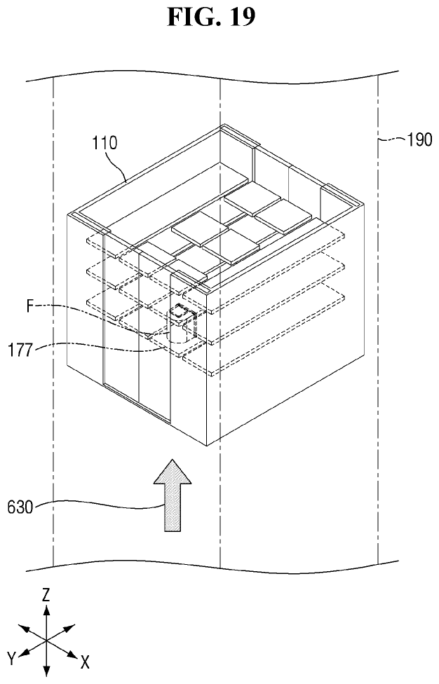

Referring to FIG. 19, the container F may be delivered from the first interface layer 310 to an arrangement unit 170 of a first inner layer 151 (which is the lowermost inner layer among three inner layers of a car 100), and in particular, to an entrance area 177 of the arrangement unit 170.

Thereafter, the car 100 may start to move to a predefined floor, as indicated by path 630.

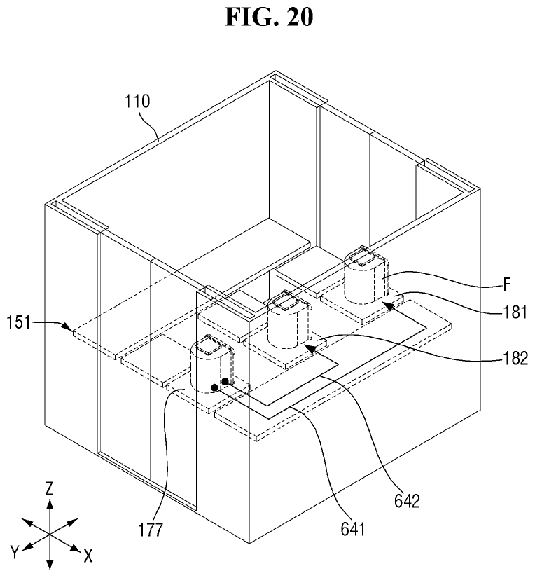

For convenience, only the first inner layer 151, which is the lowermost inner layer of the car 100, is illustrated in FIG. 20.

Referring to FIG. 20, while the car 100 is moving to the predefined floor, the arrangement unit 170 of the first inner layer 151 may move the container F to an appropriate position. For example, in a case where the container F is driven in the FIFO manner, the container F is delivered to a storage area 181 adjacent to the exit of the car 100, as indicated by path 641. In another example, in a case where the container F is driven in the LIFO manner, the container F may be delivered to a buffer 182 of the car 100, as indicated by path 642.

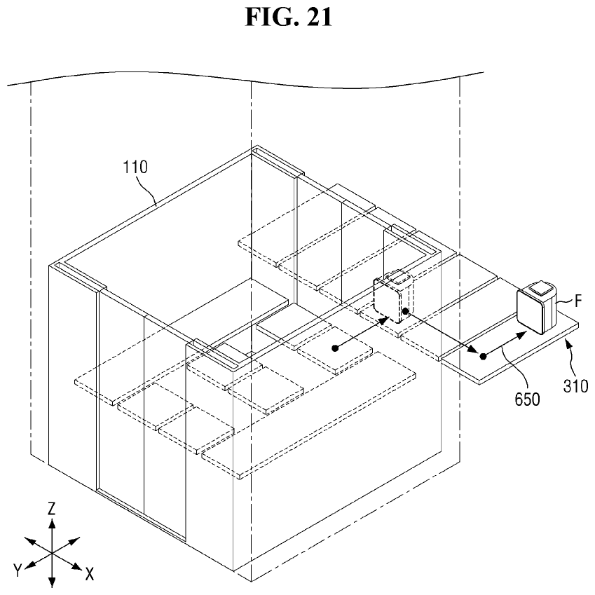

For convenience, only the first inner layer 151 of the car 100 and a first interface layer 310, which is the lowermost interface layer among three interface layers of the interface unit IF22, are illustrated in FIG. 21.

Once the car 100 arrives at the predefined floor, the container F may be delivered to the first interface layer 310 of the interface unit IF22. The container F may be moved to a loading/unloading point of the first interface layer 310 of the interface unit IF22, as indicated by path 650.

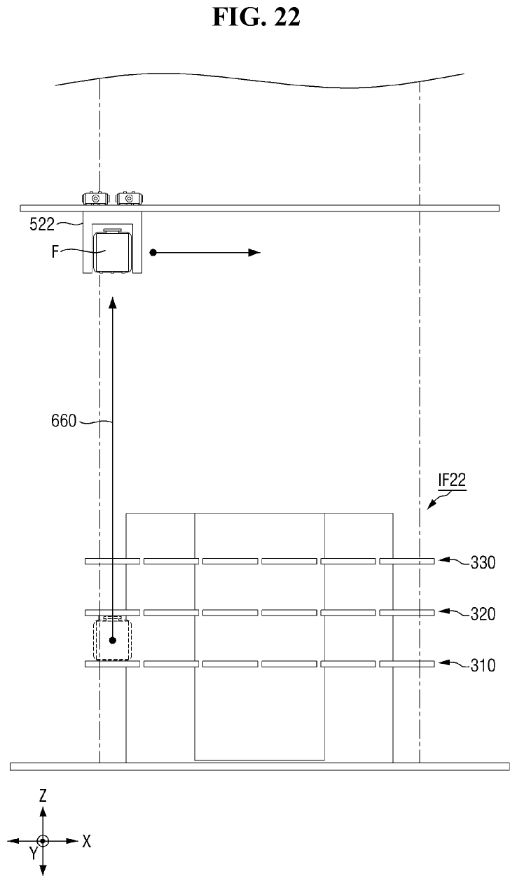

Referring to FIG. 22, the transport vehicle 522 may pick up the container F from the loading/unloading point of the first interface layer 310 of the interface unit IF22 and may move, as indicated by path 660.

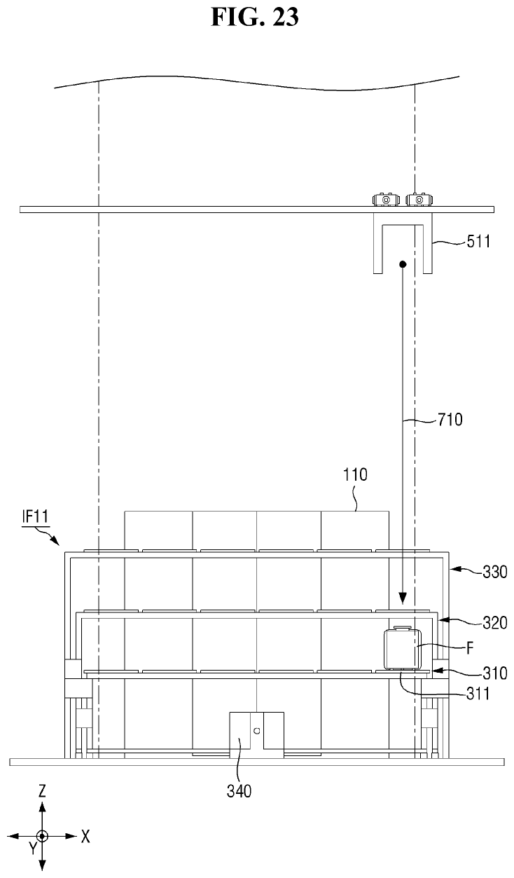

FIGS. 23, 24, 25, 26, 27, 28, 29, 30 and 31 are diagrams illustrating intermediate operations of a method of driving an inter-floor transport system according to some embodiments of the present disclosure. A method of driving an inter-floor transport system according to some embodiments of the present disclosure will hereinafter be described with reference to FIGS. 23 through 31. The inter-floor transport system that will hereinafter be described may be an exemplary inter-floor transport system having the car of FIG. 6 and the interface unit of FIG. 15 applied thereto, but the embodiments are not limited thereto.

Referring to FIG. 23, a transport vehicle 511 may unload a container F at a loading/unloading point 311 of a first interface layer 310 of an interface unit IF11, as indicated by path 710.

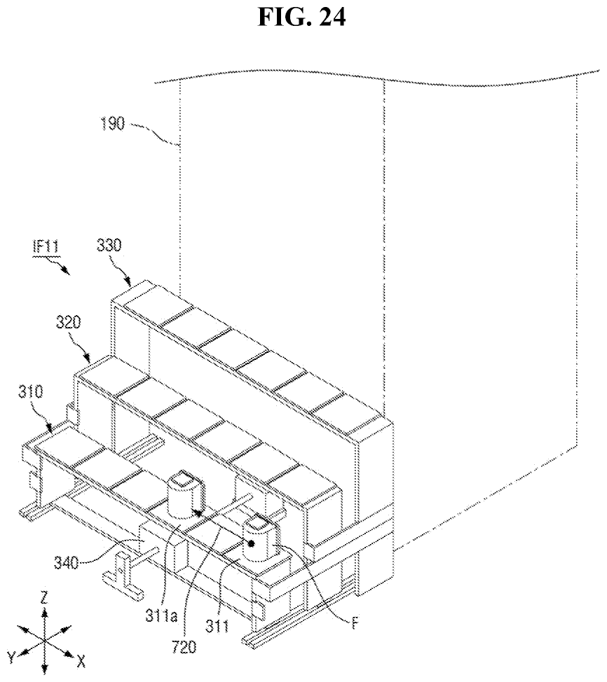

Referring to FIG. 24, the container F may be moved from the loading/unloading point 311 to an in/out point 311a of the first interface layer 310 by an interface conveyor, as indicated by path 720.

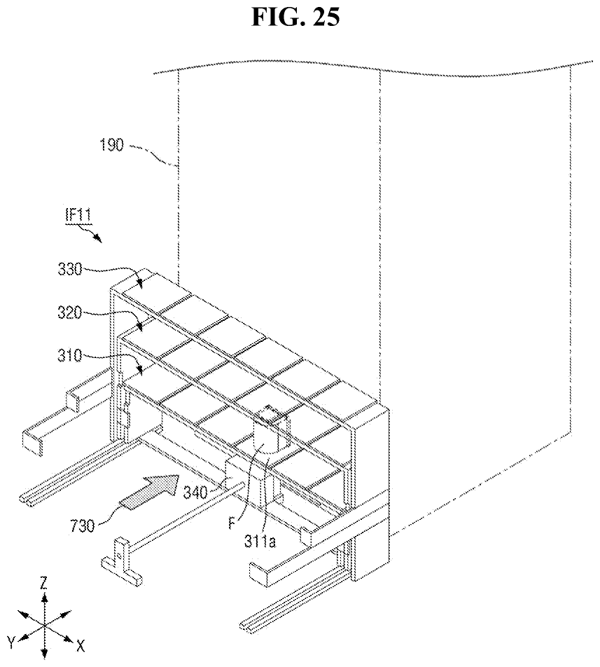

Referring to FIG. 25, the first interface layer 310 and a second interface layer 320 of the interface unit IF11 may be moved below a third interface layer 330 of the interface unit IF11 by a driver 340 of the interface unit IF11, as indicated by path 730. As a result, when viewed from above, the first and second interface layers 310 and 320 may be hidden by the third interface layer 330. Accordingly, the container F at the in/out point 311a may be positioned adjacent to the entrance of a car 100.

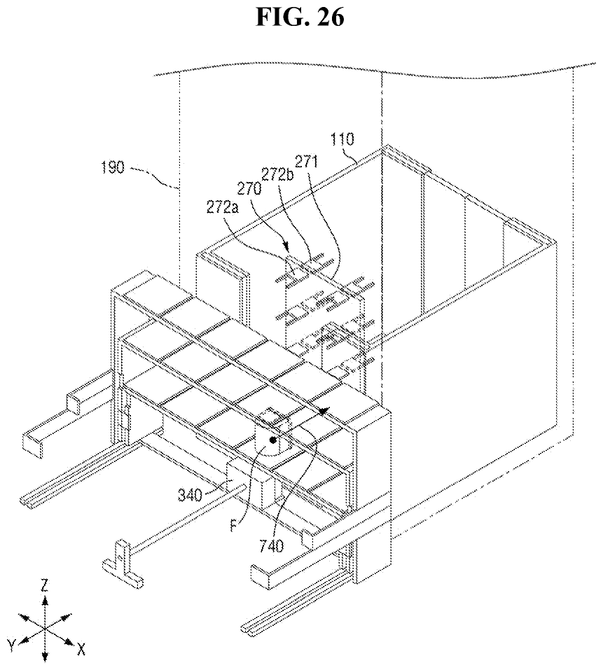

For convenience, first and second storage units 281 and 282 of a cage 110 are not illustrated in FIG. 26. Referring to FIG. 26, an arrangement unit 270 of the cage 110 may pick up the container F. Specifically, a first support 272a on a first side of a body 271 of the arrangement unit 270 may pick up the container F, as indicated by path 740. A second support 272b on a second side of the body 271 may pick up another container.

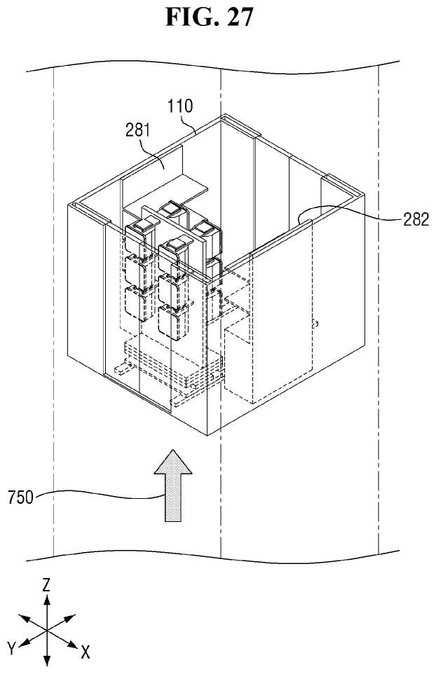

Referring to FIG. 27, the car 100 may start to move to a predefined floor, as indicated by path 750.

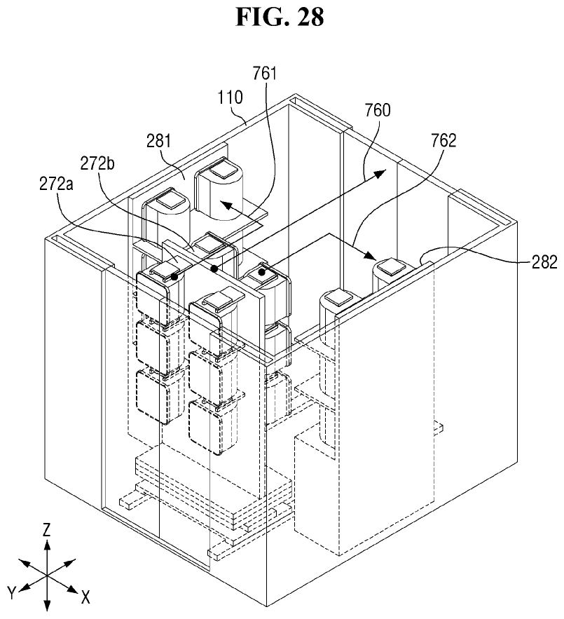

Referring to FIG. 28, while the car 100 is moving to the predefined floor, the arrangement unit 270 may change the positions of containers F.

For example, containers F held by first supports 272a of the arrangement unit 270 may be moved to, and stored in, the first storage unit 281, as indicated by path 761.

For example, containers F held by second supports 272b of the arrangement unit 270 may be moved to, and stored in, the second storage unit 282, as indicated by path 762.

Alternatively, when there is no need to store the containers in the first and second storage units 281 and 282, the arrangement unit 270 may move from the entrance to the exit of the car 100, holding the containers F, as indicated by path 760.

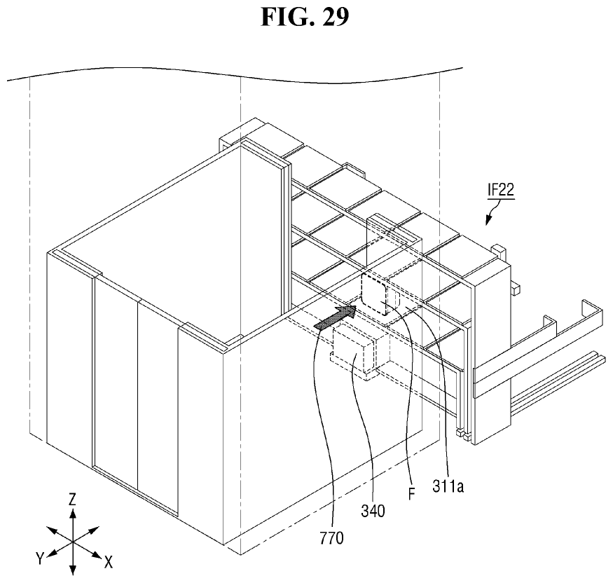

For convenience, the arrangement unit 270 and the first and second storage units 281 and 282 are not illustrated in the cage 110, in FIG. 29. Referring to FIG. 29, the arrangement unit 270 may deliver a container F to an interface unit IF22 at a delivery position, as indicated by path 770. The container F may be delivered to an in/out point 311a of a first interface layer 310 of the interface unit IF22.

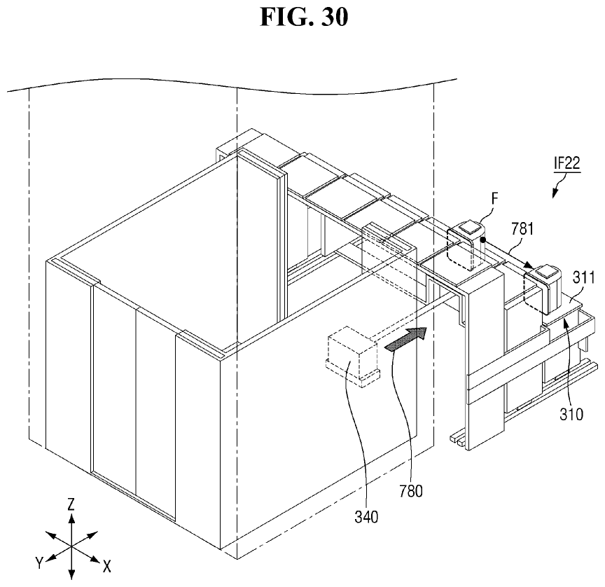

For convenience, the arrangement unit 270 and the first and second storage units 281 and 282 are not illustrated in the car 100, in FIG. 30. Referring to FIG. 30, the first interface layer 310 and a second interface layer 320 of the interface unit IF22 may be moved by a driver 340 of the interface unit IF22, as indicated by path 780. Thereafter, the container F may be moved from the in/out point 311a to a loading/unloading point 311 of the first interface layer 310 of the interface unit IF22, as indicated by path 781.

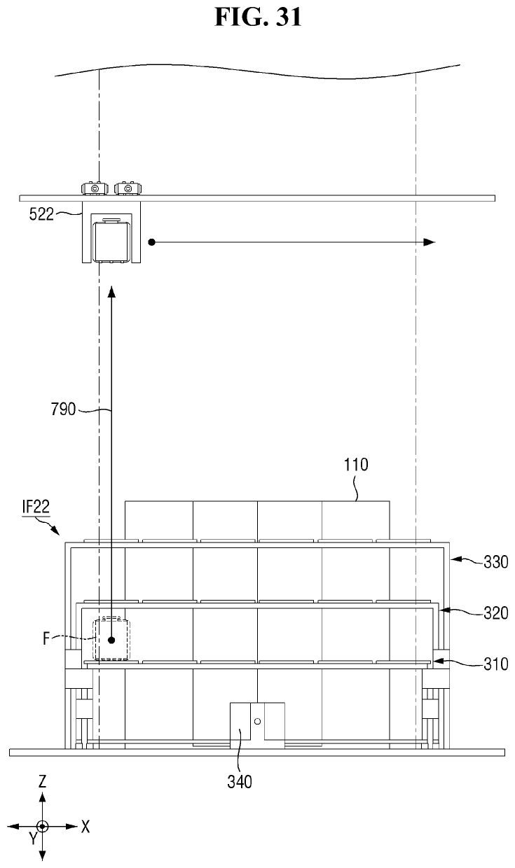

Referring to FIG. 31, a transport vehicle 522 may pick up the container F from the loading/unloading point 311 of the first interface layer 310 of the interface unit IF22 and then may move, as indicated by path 790.

According to embodiments of the present disclosure, as a car 100 moves in an elevator method and the positions of containers F are changed during the moving of the car 100, a large number of containers F may be quickly transported. That is, the transport and storage capacities of an inter-floor transport system may be enhanced, and logistics transport can may streamlined. Also, as an elevator-type car is employed, dead space is not formed even if the height of a fabrication facility increases. That is, space can be efficiently utilized.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. An inter-floor transport system comprising:
a first interface unit at a first floor and configured to receive containers from a transport vehicle; and
a car configured to:
receive containers from the first interface unit at the first floor; and
move containers to a second floor,
wherein the car comprises:
a cage,
a storage unit in the cage and comprising a plurality of storage areas, and
an arrangement unit in the cage, the arrangement unit being configured to:
receive containers from the first interface unit, and
store containers in respective storage areas of the plurality of storage areas of the storage unit.

2. The inter-floor transport system of claim 1, wherein the arrangement unit is configured to change positions of containers while the car is moving.

3. The inter-floor transport system of claim 1, wherein the arrangement unit comprises a plurality of unit conveyors, configured to move containers, and
wherein the plurality of unit conveyors are further configured to:
move containers to a respective neighboring unit conveyor of the plurality of unit conveyors, or
temporarily hold containers.

4. The inter-floor transport system of claim 3, wherein the cage comprises a first side, a second side, a third side, and a fourth side,
wherein an entrance and an exit are on the first side and the second side, respectively,
wherein the arrangement unit comprises arrangement conveyors on the third side or the fourth side, and
wherein buffers are between the arrangement conveyors.

5. The inter-floor transport system of claim 1, wherein the storage unit further comprises buffers,
wherein a first container and a second container are positioned in the cage, and
wherein the arrangement unit is further configured to move the first container is moved to one of the buffers, and to move the second container to a position that is closer to an exit of the car than a position of the first container, when the first container is to be loaded in the cage prior to the second container and is to be unloaded from the car after the second container.

6. The inter-floor transport system of claim 1, wherein the arrangement unit comprises:
a body,
a plurality of supports at the body and configured to support containers, and
a driver configured to move the body within the cage.

7. The inter-floor transport system of claim 6, wherein the cage comprises a first side, a second side, a third side, and a fourth side,
wherein an entrance and an exit are on the first side and the second side, respectively,
wherein the arrangement unit further comprises arrangement conveyors on the third side or the fourth side, and
wherein the storage unit is on at least one of the third side and the fourth side.

8. The inter-floor transport system of claim 7, wherein a layout of the plurality of supports corresponds to a layout of the plurality of storage areas.

9. The inter-floor transport system of claim 6, wherein the driver comprises:
a lift configured to move the body upward or downward, and
a slider configured to move the body horizontally.

10. The inter-floor transport system of claim 6, wherein a first container and a second container are in the cage, and
wherein the first container is held by the arrangement unit, and the second container is stored in the storage unit, when the first container is to be unloaded at the second floor and the second container is to be unloaded at a third floor after the first container is to be unloaded at the second floor.

11. The inter-floor transport system of claim 1, wherein the first interface unit comprises:
loading/unloading points where containers are to be loaded and unloaded by the transport vehicle,
in/out points where the arrangement unit is configured to receive containers, and
interface conveyors configured to move containers from the loading/unloading points to the in/out points.

12. The inter-floor transport system of claim 11, wherein each of the interface conveyors comprises a plurality of unit conveyors, and
wherein the plurality of unit conveyors are configured to move containers to a respective neighboring unit conveyor or to temporarily hold containers.

13. The inter-floor transport system of claim 12, wherein at least one of the plurality of unit conveyors comprises a diverter conveyor configured to change a moving direction of containers.

14. The inter-floor transport system of claim 1, wherein the first interface unit comprises a first interface layer and a second interface layer on the first interface layer,
wherein the storage unit comprises a first inner layer and a second inner layer, respectively corresponding to the first interface layer and the second interface layer,
wherein the first inner layer is configured to store containers delivered from the first interface layer, and
wherein the second inner layer is configured to store containers delivered from the second interface layer.

15. The inter-floor transport system of claim 14, wherein the first interface layer comprises first loading/unloading points configured to receive containers, and
wherein, when viewed from above, the first loading/unloading points are not covered by the second interface layer.

16. The inter-floor transport system of claim 14, wherein the first interface layer is configured to move between a standby position and a delivery position, and
where, when viewed from above, an overlapping area between the first interface layer and the second interface layer is larger when the first interface layer is at the delivery position than when the first interface layer is at the standby position.

17. The inter-floor transport system of claim 16, wherein the first interface layer comprises:
first loading/unloading points configured to receive containers, and
first in/out points from which the arrangement unit is configured to receive containers, and
wherein the first in/out points are not covered by the second interface layer when the first interface layer is at the standby position, but are at least partially covered by the second interface layer when the first interface layer is at the delivery position.

18. The inter-floor transport system of claim 1, further comprising:
a second interface unit at the second floor,
wherein the second interface unit is configured to receive containers from the car, and
wherein the transport vehicle is configured to pick up and transport containers received by the second interface unit.

19. An inter-floor transport system comprising:
a first interface unit at a first floor and configured to receive containers from a transport vehicle; and
a car configured to:
receive containers from the first interface unit at the first floor, and
move containers to a second floor,
wherein the car comprises:
a cage,
a storage unit in the cage and comprising a plurality of storage areas, and
an arrangement unit in the cage, the arrangement unit being configured to:
receive containers from the first interface unit, and
store containers in respective storage areas of the plurality of storage areas of the storage unit,
wherein, while the car is moving, the arrangement unit is configured to change positions of containers,
wherein the first interface unit comprises a first interface layer and a second interface layer on the first interface layer,
wherein the storage unit further comprises a first inner layer and a second inner layer respectively corresponding to the first interface layer and the second interface layer,
wherein containers delivered from the first interface layer are stored in the first inner layer,
wherein containers delivered from the second interface layer are stored in the second inner layer,
wherein the arrangement unit further comprises a plurality of unit conveyors in each of the first inner layer and the second inner layer, the plurality of unit conveyors being configured to move containers,
wherein the plurality of unit conveyors are configured to:
move containers to respective neighboring unit conveyors of the plurality of unit conveyors, or
temporarily hold containers,
wherein the first interface unit is configured to receive containers at first loading/unloading points, and
wherein, when viewed from above, the first loading/unloading points are not covered by the second interface layer.

20. A method of driving an inter-floor transport system, the inter-floor transport system comprising a first interface unit at a first floor and a car configured to move between the first floor and a second floor, the car comprising a storage unit and an arrangement unit, the method comprising:
receiving, by the first interface unit, containers from a transport vehicle,
delivering, by the first interface unit, the containers to the arrangement unit of the car; and
changing, by the arrangement unit, positions of the containers in the car by moving the containers while the car is moving.
